(19) United States
(12) Patent Application Publication
(10) Pub. No.: US 2026/0302713 A1
(43) Pub. Date: Oct. 1, 2026

(54) DUAL-ENDED AND WAVELENGTH-LOCKED OPTICAL PUMPING

(71) Applicant: Lumentum Operations LLC, San Jose, CA (US)

(72) Inventor: Martin H. MUENDEL, Oakland, CA (US)

(21) Appl. No.: 19/255,166

(22) Filed: Jun. 30, 2025

Related U.S. Application Data
(60) Provisional application No. 63/779,604, filed on Mar. 28, 2025.

(51) Int. Cl. H01S 3/0941; H01S 3/23

(52) U.S. Cl. CPC H01S 3/09415; H01S 3/2308

(57) ABSTRACT

In some implementations, an optical system includes a gain medium having a first end and a second end, a first pump diode configured to generate a first pump beam that enters the gain medium at the first end and exits the gain medium from the second end, and a second pump diode configured to generate a second pump beam that enters the gain medium at the second end and exits the gain medium from the first end. In some implementations, the optical system includes a filter, arranged between the gain medium and the second pump diode, to prevent collaborative lasing between the first pump beam and the second pump beam.

### CROSS-REFERENCE TO RELATED APPLICATION

This Patent Application claims priority to U.S. Provisional Patent Application No. 63/779,604, filed on Mar. 28, 2025, and entitled “DUAL-ENDED PUMPING WITH LOCKED PUMPS.” The disclosure of the prior Application is considered part of and is incorporated by reference into this Patent Application.

### TECHNICAL FIELD

The present disclosure relates generally to an optical pump and to dual-ended and wavelength-locked optical pumping.

### BACKGROUND

An optically pumped system typically includes a gain medium that is pumped by pump light provided by a pump source, such as a laser diode. Pumping the gain medium includes injecting the pump light into the gain medium in order to electronically excite the gain medium and/or some constituents of the gain medium into other (e.g., higher) energy levels. For example, in a laser or a laser amplifier context, optical pumping is intended to achieve a population inversion in the gain medium, and to therefore obtain optical amplification via stimulated emission for a particular range of optical frequencies (e.g., a particular gain bandwidth).

### SUMMARY

In some implementations, an optical system includes a gain medium having a first end and a second end; a first pump diode configured to generate a first pump beam that enters the gain medium at the first end and exits the gain medium from the second end; a second pump diode configured to generate a second pump beam that enters the gain medium at the second end and exits the gain medium from the first end, wherein the first pump beam and the second pump beam are each wavelength-locked; and a filter arranged between the gain medium and the second pump diode to prevent collaborative lasing between the first pump beam and the second pump beam.

In some implementations, an optical system includes a gain medium having a proximal end and a distal end; a pump diode configured to generate a first pump beam that enters the gain medium at the proximal end and exits the gain medium from the distal end; a reflective element at the distal end of the gain medium, configured to reflect the first pump beam to generate a second pump beam that enters the gain medium at the distal end and exits the gain medium from the proximal end; and a filter arranged to attenuate a portion of the second pump beam outside a desired band such that the first pump beam and the second pump beam are wavelength-locked.

In some implementations, a method includes generating, by a first pump diode, a first pump beam that enters a gain medium at a first end and exits the gain medium from a second end; generating, by a second pump diode, a second pump beam that enters the gain medium at the second end and exits the gain medium from the first end, wherein the first pump beam and the second pump beam are each wavelength-locked; and preventing, by a filter arranged between the gain medium and the second pump diode, collaborative lasing between the first pump beam and the second pump beam.

In some implementations, a method includes generating, by a pump diode, a first pump beam that enters a gain medium at a proximal end and exits the gain medium from a distal end; reflecting, by a reflective element at the distal end of the gain medium, the first pump beam to generate a second pump beam that enters the gain medium at the distal end and exits the gain medium from the proximal end; and attenuating, by a filter, a portion of the second pump beam outside a desired band such that the first pump beam and the second pump beam are wavelength-locked.

### BRIEF DESCRIPTION OF THE DRAWINGS

FIG. 1 illustrates an example optical system with dual-ended optical pumping.

FIG. 2 illustrates example optical systems implementing dual-ended and wavelength-locked optical pumping.

FIG. 3 illustrates an example optical system implementing dual-ended and wavelength-locked optical pumping.

FIG. 4 illustrates an example process for dual-ended and wavelength-locked optical pumping.

FIG. 5 illustrates an example process for dual-ended and wavelength-locked optical pumping.

### DETAILED DESCRIPTION

The following detailed description of example implementations refers to the accompanying drawings. The same reference numbers in different drawings may identify the same or similar elements.

In some cases, an optically pumped system may be designed such that a gain medium is pumped from opposing sides. For example, the system may include a first pump light source on a first side of the gain medium and a second pump light source on a second side of the gain medium opposite from the first side. In some cases, the first pump light source and the second pump light source can be the same pump light source or different pump light sources. In operation, the gain medium absorbs a portion of the first pump light and a portion of the second pump light, and transmits unabsorbed portions of the first and second pump light. For example, the gain medium may absorb approximately 80% of the first pump light and the second pump light, such that approximately 20% of both the first and second pump light is not absorbed and therefore transmitted by the gain medium. The unabsorbed portions of the pump light may propagate toward the opposing pump sources.

In some cases, given sufficient intensity, the unabsorbed portions of the first pump light and the second pump light can damage one or more elements of the optical system (e.g., due to increased temperature, melting, machining, or the like, caused by the unabsorbed portions of the first pump light and the second pump light). For example, in a case where the first pump light and the second pump light are provided by the same pump source, the unabsorbed portions of the first pump light and the second pump light can propagate to the pump source, which can result in damage. Similarly, in a case where the first pump light and the second pump light are provided by different pump sources, the unabsorbed portion of the first pump light can propagate to the second pump source and/or be reflected to the first pump source, and the unabsorbed portion of the second pump light can propagate to the first pump source and/or be reflected to the second pump source, any of which can result in damage.

The damage can occur to delivery optics associated with the optical pump, on an optical fiber associated with transporting pump light, on a source of the pump light (e.g., a laser diode chip), or the like. In some cases, the unabsorbed portions of the pump light can cause a laser diode to be unstable due to feedback, even without physical damage. Given that pump light (e.g., provided by a multi-mode fiber) is typically unpolarized, one option to protect from such damage is to include polarization-insensitive Faraday isolators in the optical pump, but these devices are expensive, are optically inefficient, and require a significant amount of physical space within the optical pump. Other techniques to address the counter-coupling through pump polarization have drawbacks, including that the gain medium degrades the polarization of the pump beam at high powers and the desired isolation effect does not work. Furthermore, coupling the pump light into only one end of the gain medium can cause thermal or saturation-related issues because the two ends of the gain medium are unequally pumped. In addition, the pump spot size may be larger than desired due to the need to combine all of the pump power into one beam. Other techniques include increasing the strength of wavelength-locking element reflectivities so that the in-band feedback substantially exceeds the out-of-band collaborative feedback, or decreasing the coupling from one pump into the other (e.g., by mismatching pump modes, spot sizes, divergences, longitudinal or transverse positions, or beam pointing). However, these solutions have shortcomings such as power inefficiencies and asymmetries.

Accordingly, some implementations described herein are related to a dual-end-pumped laser gain medium, to be pumped at or near an absorption peak of the gain medium using wavelength-locked laser diodes, with the addition of a narrow-bandpass spectral filter operating to limit the wavelength coupled from one diode pump to the other to a range of less than or approximately equal to the absorption peak. In some implementations, the laser diodes can be wavelength-locked using narrow-line reflective elements. Alternatively, in some implementations, the laser diodes may lock each other directly through the bandpass filter more efficiently than narrow-line reflective elements. In this way, when a targeted absorption peak of the gain medium is narrow compared to a natural gain linewidth of the pump beam(s), some implementations described herein maintain wavelength locking at the pump sources to induce the pump sources to lase within the desired absorption linewidth. For example, by preventing opposing locked pump beams from coupling into one another in an optical system that uses dual-ended pumping, the pump wavelength remains locked such that a significant fraction of the diode output power within the desired wavelength band couples back into the diode lasing cavity, thereby lowering the lasing threshold in the desired wavelength band so that lasing occurs preferentially in the desired wavelength band.

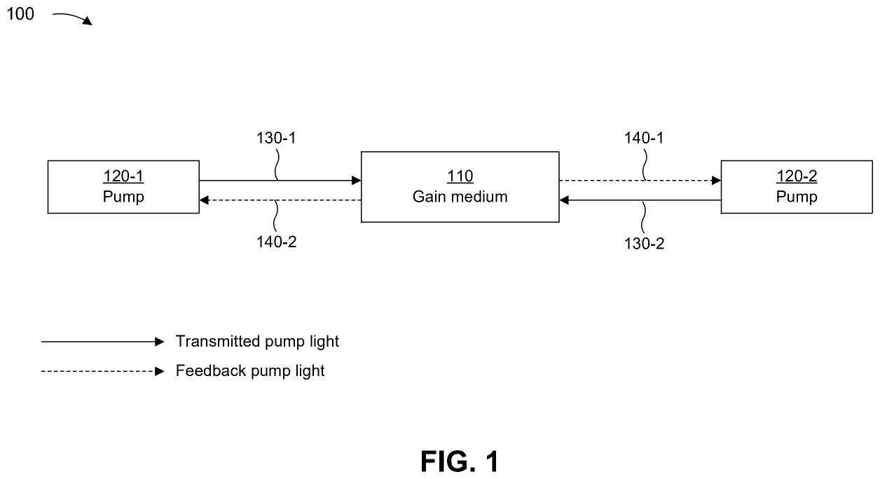

FIG. 1 illustrates an example optical system 100 with dual-ended optical pumping. As shown in FIG. 1, the optical system 100 includes a gain medium 110 that is pumped from opposing sides. For example, the optical system 100 may include a first pump light source 120-1 on a first side of the gain medium 110 and a second pump light source 120-2 on a second side of the gain medium 110 opposite from the first side. The first pump light source 120-1 and the second pump light source 120-2 can be the same pump light source or different pump light sources. In operation, the gain medium 110 absorbs a portion of first pump light 130-1 transmitted by the first pump source 120-1 and a portion of second pump light 130-2 transmitted by the first pump source 120-2. As a result, an unabsorbed portion of the first pump light 130-1 is transmitted through the gain medium 110 toward the second pump source 120-2 as feedback pump light 140-1, and an unabsorbed portion of the second pump light 130-2 is transmitted through the gain medium 110 toward the first pump source 120-1 as feedback pump light 140-2. For example, the gain medium 110 may absorb approximately 80% of the first pump light 130-1 and the second pump light 130-2, such that approximately 20% of both the first pump light 130-1 and the second pump light 130-2 is not absorbed and therefore transmitted by the gain medium 110 toward the opposite pump source 120 as feedback pump light 140.

Accordingly, when pump radiation or pump light 130 is launched into two opposed ends of the gain medium 110 (e.g., in a diode-pumped solid-state laser oscillator or amplifier), the two diode-laser pump beams 130 may each couple into the beam path of the other diode-laser pump beam 130 after transiting the gain medium 110. In some cases, such counter-coupling may be detrimental to the performance of the optical system 100. In some cases, the counter-coupling may be addressed through pump polarization. However, at high powers, the gain medium 110 degrades the polarization of the pump beams 130 and the desired isolation effect does not work. Another technique is to couple all of the pump light 130 into only one end of the gain medium 110, but in this case the two ends of the gain medium 110 are unequally pumped, which can cause thermal or saturation-related issues. In addition, the pump spot size may be larger than desired due to the need to combine all of the pump power into one beam. Other techniques include increasing the strength of locking element reflectivities in the pump sources 120 so that (desired) in-band feedback to enable wavelength locking substantially exceeds the (undesired) out-of-band collaborative feedback 140, or decreasing the coupling from one pump source 120 into the other (e.g., by mismatching pump modes, spot sizes, divergences, longitudinal or transverse positions, or beam pointing). However, these solutions have shortcomings such as power inefficiencies and asymmetries.

When pump radiation is launched into two opposed ends of the gain medium 110, one problem that arises is when a targeted absorption peak of the gain medium 110 is narrow compared to a natural gain linewidth of the pump beams 130 transmitted by the respective pump sources 120. For example, this condition may arise when the gain medium 110 is made from a material doped with ytterbium (Yb) or neodymium (Nd) on a narrow line (e.g., pumping yttrium aluminum garnet (YAG) doped with Yb (Yb: YAG) at a pump wavelength (λₚ)=969 nanometers (nm), silica fiber doped with Yb (Yb: silica) at λₚ=976 nm, or YAG or yttrium orthovanadate (YVO₄) doped with near 808 nm or 885 nm, where the absorption line half-widths are Δλₚ~1-10 nm and conventional multimode, multi-chip aluminum gallium arsenide (AlGaAs) laser diodes may have a gain spectrum half-width of Δλ_{LD}~5-15 nm or more, especially across different power levels and ambient temperatures). For narrowing the emission spectrum from the pump sources 120 (e.g., diodes), the pump sources 120 may include wavelength-locking elements such as volume Bragg gratings or on-chip gratings to induce the pump sources 120 to lase within a desired absorption linewidth. The wavelength-locking elements generally function by coupling a significant fraction (typically between 1% and 30%) of the output power from the pump sources 120 within the desired wavelength band at λₚ+/−Δλₚ back into the lasing cavity of the pump sources 120, thereby lowering the lasing threshold in the desired wavelength band so that lasing occurs preferentially in the desired wavelength band.

However, in an optical system that implements dual-ended pumping where opposing locked pump beams can couple into one another, such as optical system 100, the pump wavelength may not remain locked. For example, at wavelengths outside the desired λₚ+/−Δλₚ, the pump sources 120 have no feedback from their respective wavelength-locking elements, and therefore should not lase at such wavelengths. However, because the gain medium 110 may have little or no absorption outside the λₚ+/−Δλₚ spectral feature, the pump sources 120 can collaboratively provide the feedback pump light 140 to one another outside the band λₚ+/−Δλₚ, thereby lowering the laser threshold to a point where substantial collaborative lasing occurs between the opposed pump sources 120 outside the range λₚ+/−Δλₚ, which depletes the available useful power in the desired band and overrides conventional wavelength locking.

For example, the optical system 100 illustrated in FIG. 1 may include two locked pump sources 120, one on each end of a dual-ended gain medium 110, where the locked pump sources 120 include wavelength-locking elements with a reflectivity of 10%, the gain medium 110 has absorption of 95% within a desired band and 10% outside the desired band, and 20% of any pump light 130 transmitted through the gain medium 110 is coupled into the opposing pump source 120 as feedback pump light 140, the remaining 80% being lost to mode mismatch, misalignment, and backward propagation through the opposing pump system. The locked pump sources 120 may have direct free-space outputs or fiber-coupled outputs emerging from the fiber output tips. If the pump sources 120 lase within the desired pump band with a total diode power P from each pump source 120, each pump source 120 will receive (desired) feedback of approximately 10%×P from the wavelength-locking element, plus 90%×P×(100%-95%)×20%×90%=0.18%×P as (undesired) feedback pump light 140 from the opposing pump source 120 after traversing the locking element of the opposing pump source 120, one pass through the absorbing gain medium 110, coupling into the opposing beam path, and coupling through the locking element of the receiving pump source 120, resulting in a total feedback of 10.81%×P. Accordingly, the feedback within the desired wavelength range is dominated by the 10% strength of the locking element on that pump source 120, and the influence of the transmitted pump beam 130 from the opposing pump source 120 is minimal, due to the absorption of the gain medium 110.

However, in cases where the pumps lase outside the desired pump band, each pump source 120 can receive desired feedback of approximately 0%×P (e.g., no feedback from the locking element) plus undesired feedback 140 of approximately P×(100%-10%)×20% from the opposing diode or pump source 120, resulting in a total feedback of 18%×P. Accordingly, the feedback 140 outside the desired pump band exceeds the desired feedback within the pump band, and with the given parameters, the pump sources 120 may lase collaboratively outside of the pump band, rather than at the target wavelength set by the locking elements. As a result, the parasitic lasing could either partially or fully deplete the available useful pump power for pumping the gain medium 110.

As indicated above, FIG. 1 is provided as an example. Other examples may differ from what is described with regard to FIG. 1.

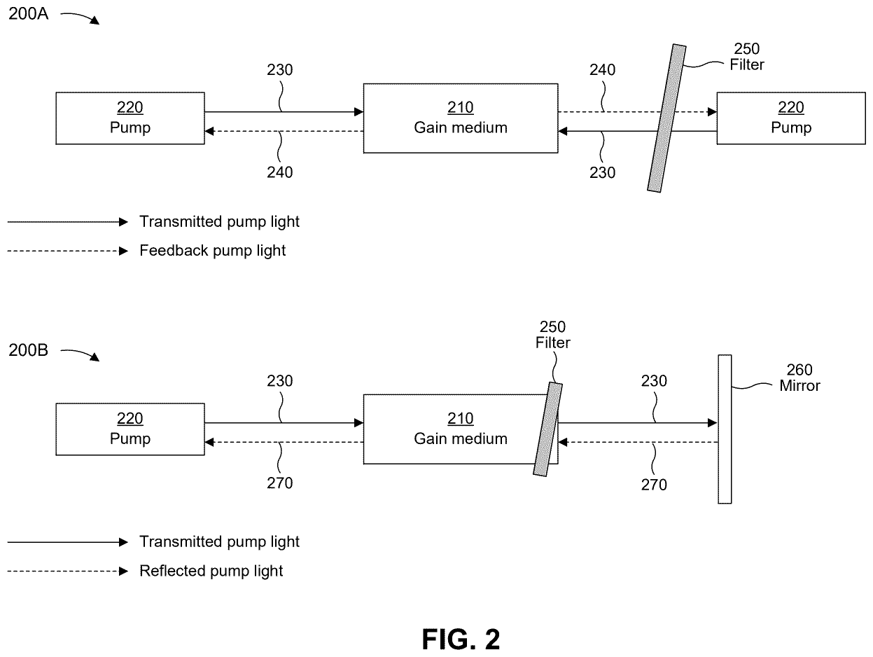

FIG. 2 illustrates an example optical system 200A and an example optical system 200B implementing dual-ended and wavelength-locked optical pumping. As shown in FIG. 2, the optical system 200A and the optical system 200B each include a dual-ended gain medium 210. As further shown in FIG. 2, the optical system 200A includes two pump sources 220 on opposing ends of the dual-ended gain medium 210, and a filter 250 (e.g., a narrow optical bandpass transmission or a notch filter) between the gain medium 210 and one of the pumps 220 to block all collaborative lasing outside a desired pump band. Alternatively, the optical system 200B includes one pump source 220 on one end of the dual-ended gain medium 210, a reflective mirror 260 at the opposite end of the dual-ended gain medium 210 to provide double-pass pump absorption, and the filter 250 may be incorporated into the gain medium 210 or the reflective mirror 260 to block undesired collaborative lasing and maintain wavelength locking.

In some implementations, as described herein, the pump sources 220 may include wavelength-locking elements such as volume Bragg gratings or on-chip gratings to induce the pump sources 220 to lase within a desired absorption linewidth. For example, in some implementations, the wavelength-locking elements in each pump source 220 may couple a portion (e.g., between 1% and 30%) of the output power of pump light 230 transmitted from the respective pump sources 220 within the desired wavelength band at λₚ+/−Δλₚ back into the lasing cavity of the pump sources 220, thereby lowering the lasing threshold in the desired wavelength band so that lasing occurs preferentially in the desired wavelength band. Furthermore, the filter 250 may be provided between the gain medium 210 and one of the pumps 220 to block feedback pump light 240 representing a portion of the pump light 230 transmitted by the opposing pump source 220 that is unabsorbed by the gain medium 210 to prevent collaborative lasing outside the desired pump band.

In some implementations, the filter 250 is designed to be narrow enough to prevent any pump lasing that bypasses an absorption line, broad enough not to clip wings of the locked pump power, and have a transmission high enough not to substantially attenuate the pump power. In some implementations, the filter 250 can be a thin-film dielectric coating filter and can be angle-tuned to optimize the wavelength of the peak transmission. In some implementations, the filter 250 may be at least slightly tilted, in order to avoid reflection of the rejected light back into the respective pump sources 120 where the rejected light could again permit out-of-band lasing. The beam paths for the rejected beams may be provided with beam blockers or absorbers to avoid uncontrolled propagation of the undesired wavelengths. In some implementations, the optical system 200A includes only one filter 250, positioned on either side of the gain medium 210. In some implementations, rather than providing a bandpass transmission function, the filter 250 may implement a notch function to reflect (rather than transmit) a desired narrow band.

In one example, the gain medium 210 may be Yb: YAG pumped within an absorption band at 969±1.0 nm by pump sources 120 that are wavelength-locked within 969±0.5 nm, and the filter 250 may have a full width transmission peak of 1.5 nm and a maximum transmission of at least 80%, or more than 90% or 95%, in order to avoid wasting pump power. In some implementations, the filter 250 may be nominally optimized for a 976 nm center wavelength at a zero-degree angle of incidence and may be used at an angle of incidence of about 10 degrees, whereby the center wavelength is shifted to about 969 nm, and fine-tuned to optimize, while the peak width and transmission are essentially unchanged. Alternatively, the filter 250 may have a 969 nm center wavelength at a particular and suitably selected angle of incidence. In some implementations, the filter 250 has a very low transmission, for example less than 20%, or less than 1%, outside the desired passband, extending at a minimum across the potential lasing range of the pump sources 220 (e.g., 10-20 nm, or up to 50-100 nm). In some implementations, the filter 250 may be fabricated using technologies such as ion-beam sputtering.

In some implementations, the wavelength-locking elements in the pump sources 220 may be omitted, and the wavelength locking may occur in each pump source 220 in response to the pump power transmitted through the gain medium 210 and through the bandpass filter 250. In this way, the added cost and optical loss of the wavelength-locking elements is avoided.

Alternatively, in some implementations, the optical system 200B may include a single pump source 220 coupled into the gain medium 210 with a reflective mirror 260 at a distal end of the gain medium 210 in order to provide double-pass pump absorption. For example, pump light 230 transmitted by the pump source 220 enters the gain medium 210 from a proximal end, exits the gain medium 210 from a distal end and is reflected by the mirror 260, and re-enters the gain medium 210 from the distal end as reflected pump light 270 to provide double-pass pump absorption. In such an arrangement, without bandpass filtering, the pump source 220 may lose wavelength locking due to the reflected pump light 270 returning to the pump source 220 from the double-pass design. Accordingly, in some implementations, the bandpass filter 250 may be incorporated on the distal end of the gain medium 210 adjacent to the double-passing mirror 260 (e.g., as shown in optical system 200B), or the double-passing mirror 260 could incorporate the narrowband filtering into a reflection spectrum. In some implementations, such an arrangement may also incorporate the features described above, where the wavelength-locking element of the pump source 220 is omitted and the wavelength-locking function is instead provided by the reflected pump light 270 returning to the single pump source 220.

As indicated above, FIG. 2 is provided as an example. Other examples may differ from what is described with regard to FIG. 2.

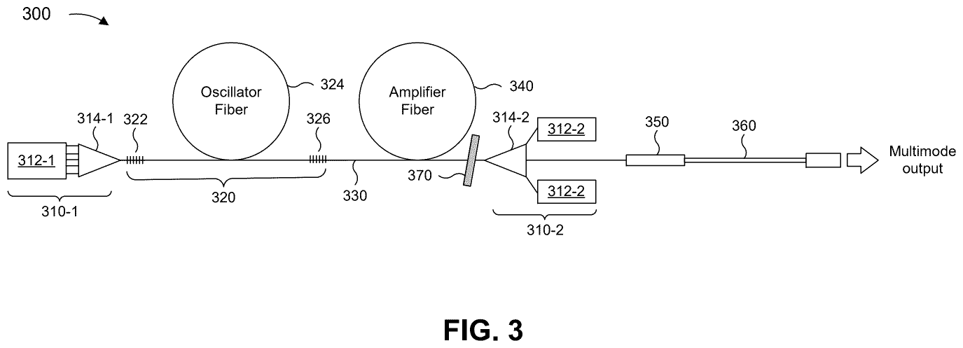

FIG. 3 illustrates an example optical system 300 implementing dual-ended and wavelength-locked optical pumping. In particular, the optical system 300 is an example master oscillator power amplifier (MOPA) laser architecture configured with a bi-directional pump to pump the oscillator and amplifier fibers to provide optical gain at a signal wavelength. For example, as shown, the bi-directional pump includes a first pump laser source 310-1 that comprises a first set of diodes 312-1 and a first combiner 314-1 provided at an input end of a master oscillator fiber 320 (e.g., to provide first pump light in a signal light propagation direction) and a second pump laser source 310-2 that comprises a second set of diodes 312-2 and a second combiner 314-2 provided at an output end of a power amplifier fiber 340 (e.g., to provide second pump light in a direction opposite from the signal light propagation direction).

As described herein, laser power scaling generally includes techniques to increase an output power from a laser without changing the geometry, shape, or principle of operation of the laser. Power scalability, which is considered an important advantage in laser design, usually requires a more powerful pump source, stronger cooling, an increase in size, and/or a reduction in background loss in a laser resonator and/or a gain medium. For example, one approach to achieving power scalability in a laser architecture is to use a MOPA architecture, such as the MOPA laser architecture shown in FIG. 3, where a fiber-based master oscillator 320 produces a highly coherent beam, and an optical power amplifier 340 increases the power of the beam while preserving the main properties of the beam. For example, the master oscillator 320 may be a low-power, single-frequency laser oscillator, and an output from the master oscillator 320 may be injected unidirectionally into the optical power amplifier 340, which has a greater output power capacity than the master oscillator 320. In some cases (e.g., as shown in FIG. 3), the power amplifier 340 may be a fiber device. In some other cases, a MOPA architecture may include a solid-state bulk laser and a bulk amplifier.

As shown in FIG. 3, the optical system 300 includes a pump source 310 that may be high powered, for example at least 100 watts (W), 1 kilowatt (kW), or multiple kW, comprising opposing sets of laser diodes 312, pump combiners 314, and output fibers coupling the laser diodes 312 and the pump combiners 314. As further shown and described herein, the optical system 300 includes the master oscillator 320 to produce a highly coherent beam. For example, the master oscillator 320 may include a first reflector 322 (e.g., a first fiber Bragg grating (FBG)), an active fiber 324, and a second reflector 326 (e.g., a second FBG). The first reflector 322 may be used as a high reflector (HR) to reflect a high percentage of signal light emitted from the active fiber 324 between the pump combiner 314 and an input end of the active fiber 324, and the second reflector 326 may be used as an output coupler at an output end of the active fiber 324. Reflectors 322 and 326 operate only at the signal wavelength and do not affect the pump light. The optical system 300 may include the power amplifier 340, a passive fiber 330 that couples the output end of the master oscillator 320 to the power amplifier 340 (e.g., via the second reflector 326 configured as the output coupler at the output end of the active fiber 324), and a signal coupler or connector 350 that is integrated with the power amplifier 340 to provide a multimode output via a delivery fiber 360. In some examples, the optical system 300 may include other components in the optical chain. For example, the laser diodes 312 may be wavelength-locked to lase within a desired absorption linewidth, and the optical system 300 may include a filter 370 to block undesired wavelengths or unabsorbed pump light to maintain or enable the wavelength locking at the laser diodes 312, as described in further detail above with reference to FIG. 2. Filter 370 may be implemented at any point in the path between and including the first set of pumps 312-1 and the second set of pumps 312-2, for example as a fiber-coupled component in the signal path, as shown, or embedded in one of the combiners 314 or in one of the sets of pumps 312.

As indicated above, FIG. 3 is provided as an example. Other examples may differ from what is described with regard to FIG. 3.

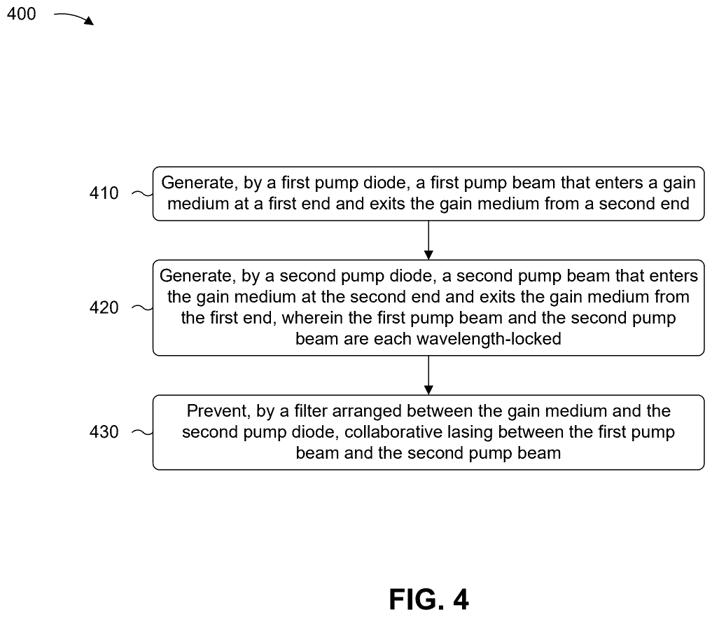

FIG. 4 is a flowchart of an example process 400 associated with dual-ended and wavelength-locked optical pumping. One or more process blocks of FIG. 4 are performed by an optical system (e.g., optical system 200A).

As shown in FIG. 4, process 400 includes generating a first pump beam that enters a gain medium at a first end and exits the gain medium from a second end (block 410). For example, the optical system may include a first pump source 220 configured to generate a first pump beam 230 that enters a gain medium 210 at a first end and exits the gain medium 210 from a second end, as described above.

As further shown in FIG. 4, process 400 includes generating a second pump beam that enters the gain medium at the second end and exits the gain medium from the first end, wherein the first pump beam and the second pump beam are each wavelength-locked (block 420). For example, the optical system may include a second pump source 220 configured to generate a second pump beam 230 that enters the gain medium 210 at the second end and exits the gain medium 210 from the first end, wherein the first pump beam 230 and the second pump beam 230 are each wavelength-locked, as described above.

As further shown in FIG. 4, process 400 includes preventing, the second pump diode, collaborative lasing between the first pump beam and the second pump beam (block 430). For example, the optical system may include a filter 250 configured to prevent collaborative lasing between the first pump beam 230 and the second pump beam 230, as described above.

Process 400 may include additional aspects, such as any single aspect or any combination of aspects described below and/or in connection with one or more other processes described elsewhere herein.

In a first aspect, the filter 250 has a high transmission within a desired passband associated with the first pump beam 230 and the second pump beam 230 and a low transmission outside the desired passband associated with the first pump beam 230 and the second pump beam 230.

In a second aspect, alone or in combination with the first aspect, the filter 250 is arranged at a non-zero angle of incidence relative to the first pump beam 230 and the second pump beam 230.

In a third aspect, alone or in combination with one or more of the first and second aspects, the non-zero angle of incidence shifts a center wavelength associated with light transmitted through the filter 250 at a zero angle of incidence to coincide with the desired passband associated with the first pump beam 230 and the second pump beam 230.

In a fourth aspect, alone or in combination with one or more of the first through third aspects, the wavelength of light transmitted through the filter 250 at the non-zero angle of incidence coincides with the desired passband associated with the first pump beam 230 and the second pump beam 230.

In a fifth aspect, alone or in combination with one or more of the first through fourth aspects, one or more structures are arranged to absorb or block a rejected portion of one or more of the first pump beam 230 or the second pump beam 230.

In a sixth aspect, alone or in combination with one or more of the first through fifth aspects, the filter 250 has a high reflection within a desired band associated with the first pump beam 230 and the second pump beam 230 and a low reflection outside the desired band associated with the first pump beam 230 and the second pump beam 230.

In a seventh aspect, alone or in combination with one or more of the first through sixth aspects, the filter 250 attenuates light of the first pump beam 230 and the second pump beam 230 that is outside a desired band over a range that includes a potential lasing range of the first pump source 220 and the second pump source 220.

In an eighth aspect, alone or in combination with one or more of the first through seventh aspects, the first pump source 220 includes one or more wavelength locking elements to lock a wavelength of the first pump beam 230 based on feedback associated with the first pump beam 230, and the second pump source 220 includes one or more wavelength locking elements to lock a wavelength of the second pump beam 230 based on feedback associated with the second pump beam 230.

In a ninth aspect, alone or in combination with one or more of the first through eighth aspects, the first pump source 220 is configured to lock a wavelength of the first pump beam 230 based on feedback 240 associated with the second pump beam 230, and the second pump source 220 is configured to lock a wavelength of the second pump beam 230 based on feedback 240 associated with the first pump beam 230.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

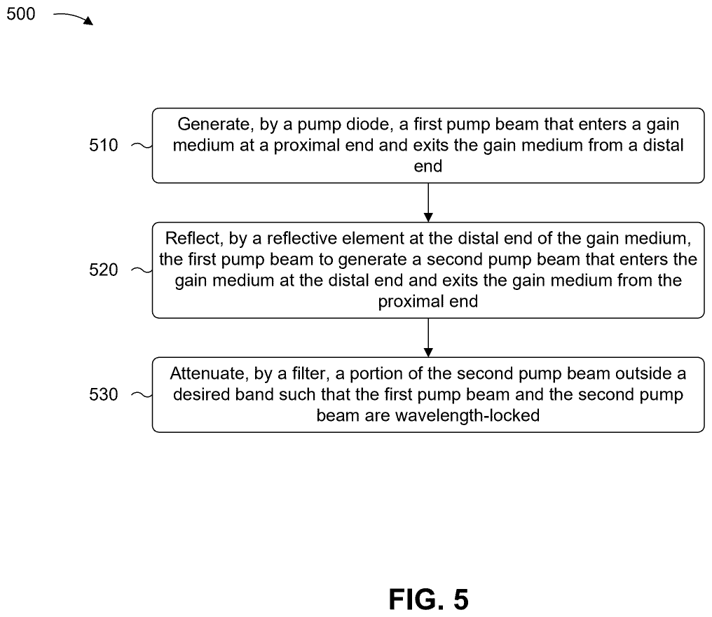

FIG. 5 is a flowchart of an example process 500 associated with dual-ended and wavelength-locked optical pumping. One or more process blocks of FIG. 5 are performed by an optical system (e.g., optical system 200B).

As shown in FIG. 5, process 500 includes generating a first pump beam that enters a gain medium at a proximal end and exits the gain medium from a distal end (block 510). For example, the optical system may include a pump source 220 configured to generate a first pump 230 beam that enters a gain medium 210 at a proximal end and exits the gain medium 210 from a distal end, as described above.

As further shown in FIG. 5, process 500 includes reflecting the first pump beam to generate a second pump beam that enters the gain medium at the distal end and exits the gain medium from the proximal end (block 520). For example, the optical system may include a mirror 260 configured to reflect the first pump beam 230 to generate a second pump beam 270 that enters the gain medium 210 at the distal end and exits the gain medium 210 from the proximal end, as described above.

As further shown in FIG. 5, process 500 includes attenuating a portion of the second pump beam outside a desired band such that the first pump beam and the second pump beam are wavelength-locked (block 530). For example, the optical system may include a filter 250 configured to attenuate a portion of the second pump beam 270 outside a desired band such that the first pump beam 230 and the second pump beam 270 are wavelength-locked, as described above.

Process 500 may include additional aspects, such as any single aspect or any combination of aspects described below and/or in connection with one or more other processes described elsewhere herein.

In a first aspect, the filter 250 is incorporated into the distal end of the gain medium 210 or the mirror 260.

In a second aspect, alone or in combination with the first aspect, the filter 250 has a low attenuation within the desired band and a low transmission outside the desired band.

In a third aspect, alone or in combination with one or more of the first and second aspects, the filter 250 is arranged at a non-zero angle of incidence relative to the first pump beam 230 and the second pump beam 270.

In a fourth aspect, alone or in combination with one or more of the first through third aspects, the non-zero angle of incidence shifts a center wavelength associated with light transmitted through the filter 250 at a zero angle of incidence to coincide with the desired band.

In a fifth aspect, alone or in combination with one or more of the first through fourth aspects, the wavelength of light transmitted through the filter 250 at the non-zero angle of incidence coincides with the desired band.

In a sixth aspect, alone or in combination with one or more of the first through fifth aspects, one or more structures are arranged to absorb or block a rejected portion of one or more of the first pump beam 230 or the second pump beam 270.

In a seventh aspect, alone or in combination with one or more of the first through sixth aspects, the filter 250 has a high reflection within the desired band and a low reflection outside the desired band.

In an eighth aspect, alone or in combination with one or more of the first through seventh aspects, the filter 250 attenuates the portion of the second pump beam 270 outside the desired band over a range that includes a potential lasing range of the pump source 220.

In a ninth aspect, alone or in combination with one or more of the first through eighth aspects, the pump source 220 includes one or more wavelength locking elements to lock a wavelength of the first pump beam 230 based on feedback associated with the first pump beam 230.

In a tenth aspect, alone or in combination with one or more of the first through ninth aspects, the pump source 220 is configured to lock a wavelength of the first pump beam 230 based on feedback associated with the second pump beam 270.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “front,” “back,” “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical system, comprising:
a gain medium having a first end and a second end;
a first pump diode configured to generate a first pump beam that enters the gain medium at the first end and exits the gain medium from the second end;
a second pump diode configured to generate a second pump beam that enters the gain medium at the second end and exits the gain medium from the first end, wherein the first pump beam and the second pump beam are each wavelength-locked; and
a filter arranged between the gain medium and the second pump diode to prevent collaborative lasing between the first pump beam and the second pump beam.

2. The optical system of claim 1, wherein the filter has a high transmission within a desired passband associated with the first pump beam and the second pump beam and a low transmission outside the desired passband associated with the first pump beam and the second pump beam.

3. The optical system of claim 2, wherein the filter is arranged at a non-zero angle of incidence relative to the first pump beam and the second pump beam.

4. The optical system of claim 3, wherein the non-zero angle of incidence shifts a center wavelength associated with light transmitted through the filter at a zero angle of incidence to coincide with the desired passband associated with the first pump beam and the second pump beam.

5. The optical system of claim 3, wherein the wavelength of light transmitted through the filter at the non-zero angle of incidence coincides with the desired passband associated with the first pump beam and the second pump beam.

6. The optical system of claim 1, further comprising:
one or more structures arranged to absorb or block a rejected portion of one or more of the first pump beam or the second pump beam.

7. The optical system of claim 1, wherein the filter has a high reflection within a desired band associated with the first pump beam and the second pump beam and a low reflection outside the desired band associated with the first pump beam and the second pump beam.

8. The optical system of claim 1, wherein the filter attenuates light of the first pump beam and the second pump beam that is outside a desired band over a range that includes a potential lasing range of the first pump diode and the second pump diode.

9. The optical system of claim 1, wherein the first pump diode includes one or more wavelength locking elements to lock a wavelength of the first pump beam based on feedback associated with the first pump beam, and wherein the second pump diode includes one or more wavelength locking elements to lock a wavelength of the second pump beam based on feedback associated with the second pump beam.

10. The optical system of claim 1, wherein the first pump diode is configured to lock a wavelength of the first pump beam based on feedback associated with the second pump beam, and wherein the second pump diode is configured to lock a wavelength of the second pump beam based on feedback associated with the first pump beam.

11. An optical system, comprising:
a gain medium having a proximal end and a distal end;
a pump diode configured to generate a first pump beam that enters the gain medium at the proximal end and exits the gain medium from the distal end;
a reflective element at the distal end of the gain medium, configured to reflect the first pump beam to generate a second pump beam that enters the gain medium at the distal end and exits the gain medium from the proximal end; and
a filter arranged to attenuate a portion of the second pump beam outside a desired band such that the first pump beam and the second pump beam are wavelength-locked.

12. The optical system of claim 11, wherein the filter is incorporated into the distal end of the gain medium or the reflective element.

13. The optical system of claim 11, wherein the filter has a low attenuation within the desired band and a high attenuation outside the desired band.

14. The optical system of claim 11, wherein the filter is arranged at a non-zero angle of incidence relative to the first pump beam and the second pump beam.

15. The optical system of claim 14, wherein the non-zero angle of incidence shifts a center wavelength associated with light transmitted through the filter at a zero angle of incidence to coincide with the desired band.

16. The optical system of claim 14, wherein the wavelength of light transmitted through the filter at the non-zero angle of incidence coincides with the desired band.

17. The optical system of claim 11, further comprising:
one or more structures arranged to absorb or block a rejected portion of one or more of the first pump beam or the second pump beam.

18. The optical system of claim 11, wherein the filter has a high reflection within the desired band and a low reflection outside the desired band.

19. The optical system of claim 11, wherein the filter attenuates the portion of the second pump beam outside the desired band over a range that includes a potential lasing range of the pump diode.

20. The optical system of claim 11, wherein the pump diode includes one or more wavelength locking elements to lock a wavelength of the first pump beam based on feedback associated with the first pump beam.

21. The optical system of claim 11, wherein the pump diode is configured to lock a wavelength of the first pump beam based on feedback associated with the second pump beam.

22. A method, comprising:
generating, by a first pump diode, a first pump beam that enters a gain medium at a first end and exits the gain medium from a second end;
generating, by a second pump diode, a second pump beam that enters the gain medium at the second end and exits the gain medium from the first end, wherein the first pump beam and the second pump beam are each wavelength-locked; and
preventing, by a filter arranged between the gain medium and the second pump diode, collaborative lasing between the first pump beam and the second pump beam.

23. A method, comprising:
generating, by a pump diode, a first pump beam that enters a gain medium at a proximal end and exits the gain medium from a distal end;
reflecting, by a reflective element at the distal end of the gain medium, the first pump beam to generate a second pump beam that enters the gain medium at the distal end and exits the gain medium from the proximal end; and
attenuating, by a filter, a portion of the second pump beam outside a desired band such that the first pump beam and the second pump beam are wavelength-locked.
